(19) United States
(12) Patent Application Publication
(10) Pub. No.: US 2016/0218048 A1
(43) Pub. Date: Jul. 28, 2016

(54) MICROFLUIDIC CHANNELS FOR THERMAL MANAGEMENT OF MICROELECTRONICS

(71) Applicant: Nuvotronics Inc., Radford, VA (US)

(72) Inventors: Hooman Kazemi, Thousand Oaks, CA (US); Mark Crawford, Christiansburg, VA (US); Aaron Caba, Blacksburg, VA (US); David Sherrer, Cary, NC (US)

(21) Appl. No.: 15/006,535

(22) Filed: Jan. 26, 2016

Related U.S. Application Data
(60) Provisional application No. 62/108,006, filed on Jan. 26, 2015.

(51) Int. Cl. H01L 23/473

(52) U.S. Cl. CPC H01L 23/4735

(57) ABSTRACT

Heat spreading device using microfabricated microfluidic structures to cool microelectronic devices.

### RELATED APPLICATIONS

This application claims the benefit of priority of U.S. Provisional Application No. 62/108,006, filed on Jan. 26, 2015, the entire contents of which application(s) are incorporated herein by reference.

### GOVERNMENT LICENSE RIGHTS

The subject matter of the present application was made with government support from the Defense Advanced Research Projects Agency under contract number FA8650-14-C-7468. The government may have rights to the subject matter of the present application.

### FIELD OF THE INVENTION

The present invention relates generally to cooling solutions on the micro scale, and more particularly, but not exclusively, to cooling at locations that are near microelectronic circuits.

### BACKGROUND OF THE INVENTION

One of the major limiting factors in many electronic systems is the thermal management of the power dissipated by these systems. This is the case in many defense and commercial products including such devices as microprocessors, high-power RF amplifiers, analog or digital processors, lasers or optoelectronic devices, high brightness light emitting diodes, and so forth. The subject invention presents structures and processes of manufacturing that spread the waste heat created by the device of interest from as close as possible to such device without necessarily needing to employ special fabrication processes on the device itself, thus providing a solution that may be employed for a variety of heat-generating devices.

### SUMMARY OF THE INVENTION

In one of its aspects the present invention may relate to structures and processes of formation used to create thermal heat spreaders and exchangers for microelectronics packaging. As used herein the term “thermal spreader” is defined to describe an integrated heat spreader that includes a fluidic heat exchanger having fluidic distribution and flow regions, which cooperate to distribute heat from a heat generating device disposed in thermal communication with the thermal spreader. The heat exchanger may remove heat to the outside world (through fans blowing air on a series of metal fins, fluid that is expelled into the environment, high surface area fluid chambers that have air blown across them like a radiator in a refrigeration system, or by other means). In another of its aspects the present invention may provide thermal spreaders that are available for commercial-off-the-shelf (COTS) microelectronics; however, devices and methods of the present invention may be applied to custom-fabricated devices.

Devices of the present invention may provide interconnection and a suitable operating environment for electrical circuits, such as in a packaging context, for example. Packaging may provide four main functions: (1) signal distribution, primarily involving topology and electromagnetic considerations; (2) power distribution, involving electromagnetic, material, and structural considerations; (3) heat dissipation, involving structural and material considerations; and (4) protection, concerning mechanical, chemical, and electromagnetic considerations for components and interconnections.

Generally, five levels may be used in classic electronic packaging. Level 0 packaging is the packaging involved on the IC chip or die itself. Level 1 packaging is concerned with moving from a die or dice taken from wafers and packaging them into a single chip module or multi-chip module resulting in a packaged chip. Here the “packaged chip” while a singular part, may in fact contain multiple Level 0 die. Second Level or Level 2 packaging is concerned with printed circuit boards or cards. Level 3 packaging is card-on-board or a backplane related packaging. Level 4 is cabinet or enclosure packaging or system level packaging of such enclosures. As packaging has evolved there has been some blurring between these classical boundaries. For example, the MCM or multi-chip module may disguise multiple Level 0 die as a single Level 1 packaged chip; also COB or “chip on board” which may place a Level 0 die onto a Level 2 circuit board by adding some steps at Level 0 (such as pillar bump) and Level 2 (such as underfill and encapsulants) to apparently bypass a Level 1 independent “packaged chip.”

For microelectronics, the closer that one can get to the Level 0 heat source with a thermal spreader of the present invention, the easier it will be to remove the heat and maintain low operating temperatures near the heat generating region. A Level 0 packaging change would be to either grow the microelectronic circuit on a different wafer or substrate material or to modify the substrate or wafer material on which the microelectronic circuit is grown. In a first case, this could mean thinning the wafer and transferring the microelectronic circuits to a higher thermal conductivity substrate such as man-made diamond wafers. In a second case, this could mean cutting channels into the wafer using reactive ion etching, laser machining, or other methods. In either case, these are new process steps that disrupt the already-established semiconductor fabrication processes in practice (and may require re-design of the circuits, as well). Although the present invention could be applied in such a manner, it is envisioned as a process that could be used on finished wafers or individual die. For illustrative purposes, the problem will be described hereafter with reference to an exemplary RF power amplifier die built using high electron mobility transistors (HEMTs) on Gallium Nitride (GaN).

In such an exemplary device, the transistor channel temperature sets both the long-term lifetime of the device and the immediate device gain decreases as channel temperature increases (in the example of an amplifier). The heat generated in this channel may be transported and spread first using a Level 0 thermal spreader of the present invention which is first the substrate of the die, then through a series of thermal interfaces to some location where it will ultimately be dissipated with a heat exchanger to what might generally be the outside world. In the case of a central processing unit (CPU) in a computer, there may be a copper heat sink which is directly attached to the die or a level 1 package of the die, and then connected to a liquid-cooled thermal spreader of the present invention that is mounted to the back of the integrated circuit package which removes heat to a heat exchanger which may be a series of metal fins which have a fan blowing on them to exchange the heat with the air within the computer case (Level 4), which is then released into the surrounding environment using fans on the computer case.

In the case of the present invention, the thermal spreader may include the heat sink, to which the die is attached, which can greatly reduce the thermal resistance of the package. In this case the thermal spreader may be used, because the heat source can have a high heat-flux density and the heat may first be spread out by the spreader, and then once spread to a larger surface area; the lower heat conduction of a fluid (e.g., a liquid) is addressed by the higher surface area of spreaders so heat may be removed more effectively. One of the limiting aspects of this scenario may include the physical distance between the heat-generating points of the CPU chip to the copper pipe that has fluid within it which transports the heat to the heat exchanger which may transfer the heat to the air with a fan. Depending on the boundary conditions surrounding the CPU, for a given amount of dissipated power generated by the CPU, a higher maximum temperature will exist. Devices of the present invention can reduce this distance from the heat generating points of the CPU chip to the fluid-containing pipes to the extent possible and improve thermal performance. In particular, devices of the present invention may be well suited to application to a Level 0 or a Level 1 thermal packaging solution.

Regardless of the primary Level 1 heat sink being constructed, both Level 0 and Level 1 heat transfer is limited by the thermal conductivity of the materials used and their thicknesses in the path of the heat. When exchanging the heat from a heat source to a fluid that is cooling and transporting the heat away, the heat transfer between a solid and a fluid (liquid or gas) may be also fundamentally limited by the (1) surface area and (2) rate of flow of a fluid thermal transport medium across the “hot spots” on the solid Level 0 (die) or Level 1 (packaged chip's) solid heat sink materials. This realization made in connection with development of the present invention (that the “heat sink” or primary thermal conduction materials should be as close as possible to the source of the heat in an active device), combined with the challenges of providing both a large surface area and sufficiently high levels of fluid flow across the critical hot regions on these surfaces, creates a sophisticated engineering challenge that is not addressed simply.

In another of its aspects, devices and structures of the present invention may include large surface areas that may be created by microstructures within the channels through which the heat transfer fluid flows. Current fluidic cooling technology increases the surface area using a variety of means such as straight-walled grooves, sintered copper spheres, etc. The present invention employs advanced manufacturing techniques to increase surface area with greater control and more freedom. These microstructures may or may not create non-laminar (or turbulent) flow within the channels. The efficacy of this inventive concept has been validated by careful finite element analysis and fluidic analysis, which verified the utility of more complex and deliberately designed solutions using microstructures, materials, thermal and flow design.

Optimizing such systems requires complex fluid dynamic analysis for both heated fluid flows in a heat exchanger and heat sink system. Moreover, solutions of the present invention can be applied and optimized for both single-phase and two-phase fluidic coolants. By making the thermal spreader using microfabrication, a spreader may contain smaller features than are achievable using traditional fabrication means. A larger surface area for cooling can be created using fabrication methods where the smallest dimensions for fins and channels are on the order of 10 to 50 microns instead of 150 or more with traditional machining. As such, an additive build process may be used to make fluidic channels described herein. There are many ways to build these channels; however having the ability to independently define arbitrary geometries on a layer-by-layer basis can be important for removal of heat from high-density heat sources. One such process is the PolyStrata® technology offered by Nuvotronics, Inc. and described in the patent documents, such as: U.S. Pat. Nos. 7,012,489, 7,649,432, 7,948,335, 7,148,772, 7,405,638, 7,656,256, 7,755,174, 7,898,356, 8,031,037, 2008/0199656 and 2011/0123783, 2010/0296252, 2011/0273241, 2011/0181376, 2011/0210807, the contents of which are incorporated herein by reference. Such structures may also be made using other forms of additive manufacturing, such as three-dimensional printing, however the feature resolution is currently not as high, which may limit the performance of such devices.

As liquids and gasses are relatively poor thermal conductors, exemplary designs in accordance with the present invention may rely on spreading the heat from the heat source to a large surface area using a high-thermal-conductivity solid material and then removing the heat with the liquid or fluid. However, in one of the aspects of the present invention, surface area is not the only factor that may be utilized for heat removal. A fluid interacting with the surface must take the heat into itself and once heated move away so that cooler fluid can move in and take its place. Thus, fluidic flow factors may be addressed in an inventive aspect of the present invention, such as by providing a structure for disrupting the fluid flow locally and by increasing the mass flow of the fluid. Local structures may be provided to effect fluid flow disruption and increased mass flow; exemplary structures may include nozzles, obstructions, baffles, diverters, apertures, and other structures such as ones that may have parallels in traditional larger fluidic systems. These structures may be local to remove excess heat from pre-determined hot spots of the device. Alternatively, the local structures may be repeated across the entire surface area proximate the microelectronic being cooled. Forcing fluid through fins of increasingly smaller feature sizes requires an increase in pressure drop between two points of interest, but also provides greater heat transfer with greater surface area for a given mass flow. By taking advantage of localized three-dimensional microstructures within channels, more heat transfer may occur within larger channels with less pressure drop than would be achievable with simple grooves. Such structures are also less likely to clog with contaminating particles or require additive particles than smaller basic channels with similar heat transfer rates.

It is also possible using microfabrication to introduce motion into the microfluidic system using actuators and/or active materials so that valves, pumps, and flow regulators and diverters may be incorporated. Small sensors and independent heat sources may also be included, for example, to measure mass and fluid flow, heat flow, and/or to provide means for creating an adaptive cooling system that diverts coolant to the areas that most require it. This can be useful for applications such as cooling CPU and GPU chips where areas of the chip may heat differentially with time depending on the cores being used for a given set of operations.

In addition to local structures that may be used to remove heat from the spreader, an aspect of the present invention may be directed to methods for distributing the liquid to the regions of interest and recuperating that liquid from the thermal spreader. Tapered regions may be provided in exemplary devices of the present invention to transition between channels of different cross sections with minimal pressure drop. Transitions may be made for standard pipes and fittings to the microfabricated thermal spreader—if for test purposes only, if not for closed-loop systems. In addition to transitions between the microfabricated devices and standard microfluidics, transitions between multiple microfabricated devices may be provided.

As a thermal spreader of the present invention may be created from the combination of multiple parts, sealing these parts may be important when fluids in liquid or gas state are involved. Thus, in another of its aspects the present invention may provide a copper gasket that is microfabricated as a good way of making one or more of these seals. Other materials than copper may be used that are softer or that have particular mechanical or chemical properties that are desirable. For example, an indium gasket may be created and then coated with a gold layer to make it more chemically inert or impart other desirable mechanical properties. Additionally, the gasket does not necessarily have to be electrically conductive. While such gaskets may be formed in a mold, it is possible that stamping or cutting by other means may be preferred. By using microfabrication techniques such as electroplating the gasket in a patterned mold, such as a photoresist mold, and then removing the gasket from the mold or dissolving the mold material, or by chemical etching, the gasket may have an unusual pattern, which may be necessary given the small features required to attach to microelectronics. The gasket may, for example, be patterned to join flange regions on two metal surfaces while not obstructing flow between integrated nozzles, plumbing, or areas for return flow. The microfabricated gasket can have better in-plane tolerances and finer or more complex features than gaskets formed by traditional operations such as progressive stamping. Additionally, the thickness of the microfabricated gasket may be varied over the surface of the gasket in well controlled steps. This could be used to provide different areas of the seal with different pressures, make up extra tolerances, or provide for different crush of the gasket in different areas.

The attachment of a microfabricated thermal spreader of the present invention to a microelectronic device to be cooled is also an important consideration. If the thermal spreader is a copper-based material or other standard metal, it is important to important to consider methods to match the coefficient of thermal expansion between the microelectronics device (consider it a semiconductor integrated circuit in bare die form) and the thermal spreader. Matching the coefficient of thermal expansion could be achieved using an engineered pattern in the copper to limit the thermal expansion mismatch or provide flexible compliance where the two materials are joined. The material used to join the integrated circuit to the thermal spreader may be a solder, a conductive epoxy, an anisotropic adhesive, or the thermal spreader may be grown on the backside of the IC—either the entire wafer of ICs at once, a group of them, or on a chip-by-chip basis. Alternatively, a stack of materials of varying thickness values and coefficients of thermal expansion may be employed to reduce the stress from IC to the predominate material of the thermal spreader. Such a stack could be electroplated as part of the fabrication process for the thermal spreader.

In addition to the fluidic connections, mechanical connections may also be required, which can be fabricated by defining alignment features which take advantage of the realizable geometric tolerance of the microfabrication process. These alignment features may use the outer dimensions or inner dimensions of the fluidic channels to which they are attached.

Notwithstanding the preceding descriptions regarding single-phase thermal management devices, similar geometries and fabrication techniques may be used for dual-phase thermal management systems. In these systems, not just a liquid, but both the liquid and gas phases of a particular fluid are used. This phase-phase transition either requires a great deal of energy or gives up a great deal of energy (depending on whether it is going from liquid to gas or the other way around). In both single- and two-phase systems, sealing the system to prevent loss of the gas or liquid is important. In a layer-by-layer process, this may be done using the PolyStrata® process which forms fused layers, or by stacking pre-patterned layers and fusing those layers. When fusing pre-patterned layers, metal-metal direct thermocompression bonding, or providing an intermediary coating to facilitate bonding, any known means of sealing surfaces may be used. Due to the complexity that may be involved in a complex cooling microsystem, sealing the system at the perimeter of the layers may be a challenge and it may be preferable to enclose the microsystem in a sealed box or other secondary packaging whose primary purpose may be to contain a gas phase of a two phase cooling fluid.

### BRIEF DESCRIPTION OF THE DRAWINGS

The foregoing summary and the following detailed description of exemplary embodiments of the present invention may be further understood when read in conjunction with the appended drawings, in which:

FIG. 1 schematically illustrates exemplary constitutive concepts and structures of the subject invention;

FIGS. 2A-2B schematically illustrate cross-sectional views of an exemplary configuration of components of a thermal spreader in accordance with the present invention, along with the microelectronic device that the spreader is cooling;

FIG. 2C schematically illustrates FIGS. 2A and 2B in a perspective view with additional details shown;

FIG. 2D illustrates a computer simulation showing how various flow disrupting structures may be located between the fins to optimize flow velocity;

FIGS. 3A-3B schematically illustrate top and bottom isometric views, respectively, of an exemplary configuration of a microfabricated thermal spreader in accordance with the present invention;

FIG. 3C schematically illustrates an isometric view of another exemplary configuration of a microfabricated thermal spreader in accordance with the present invention;

FIGS. 4A-4B schematically illustrate top and bottom isometric views, respectively, of an exemplary configuration of a ‘chandelier’-style fluidic distribution device in accordance with the present invention;

FIG. 5 schematically illustrates an exemplary configuration of a local distribution structure in accordance with the present invention for fluidic delivery and fluidic thermal exchange between a spreader and a microelectronic circuit;

FIG. 6 schematically illustrates an exemplary apparatus for attaching a microfluidic thermal spreader of the present invention to standard plumbing fittings;

FIG. 7 schematically illustrates an exploded view of an assembly in accordance with the present invention including a microelectronic device being cooled, a microfabricated thermal spreader, a microfabricated gasket, and other components; and

FIG. 8 schematically illustrates simulations of deformation of a microfabricated gasket in accordance with the present invention used to seal a microfluidic system.

### DETAILED DESCRIPTION OF THE INVENTION

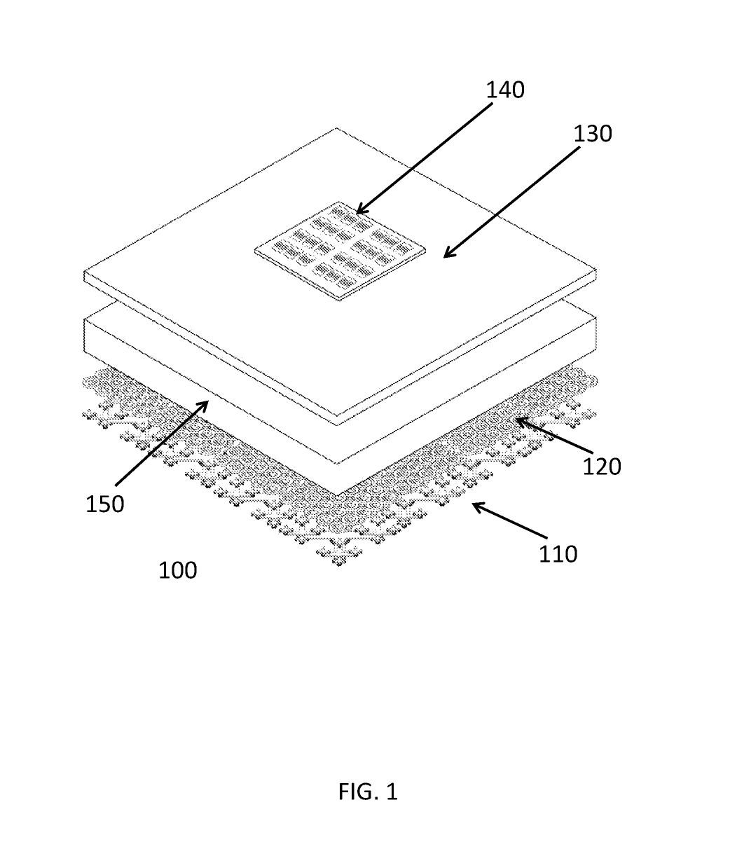

Referring now to the figures, wherein like elements are numbered alike throughout, FIG. 1 shows an exploded view illustrating several concepts of the present invention. A microelectronic device 140 (here assumed to be a GaN HEMT array) is bonded with a stress transition stack (or other thermal interface material) 130 to an integrated thermal spreader 150. Within the integrated thermal spreader 150 are micro-structured thermal spreaders 120 to which fluid is distributed and optionally retrieved using a fluidic manifold 110 here shown as a fluidic distribution network.

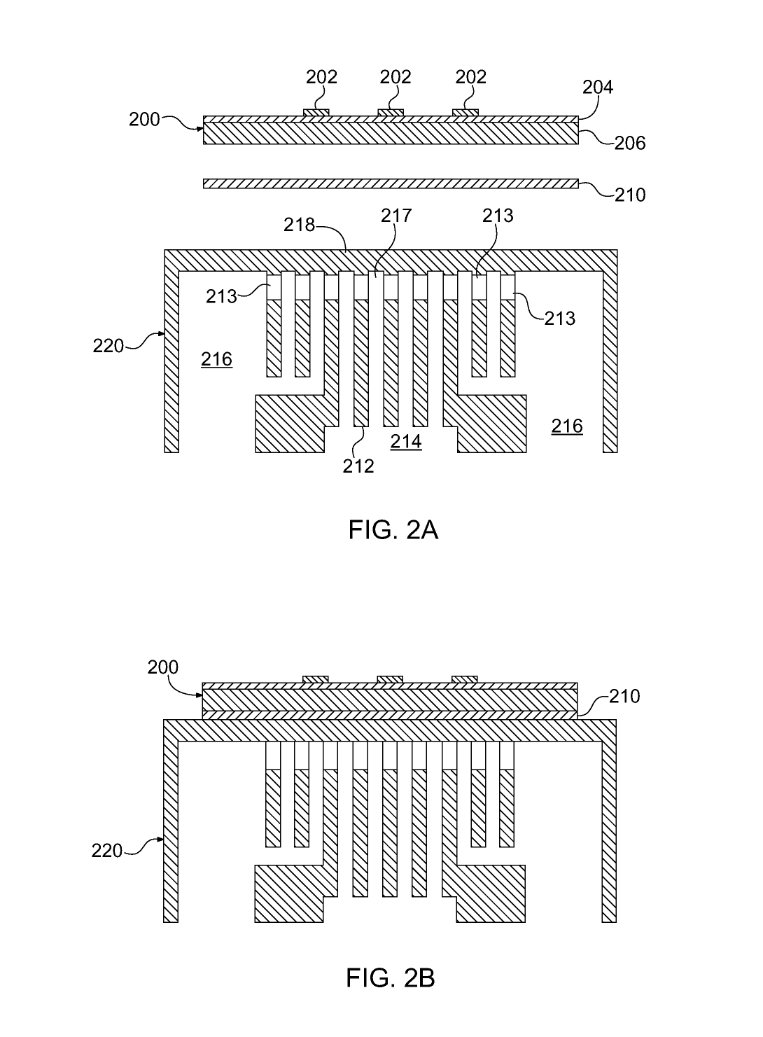

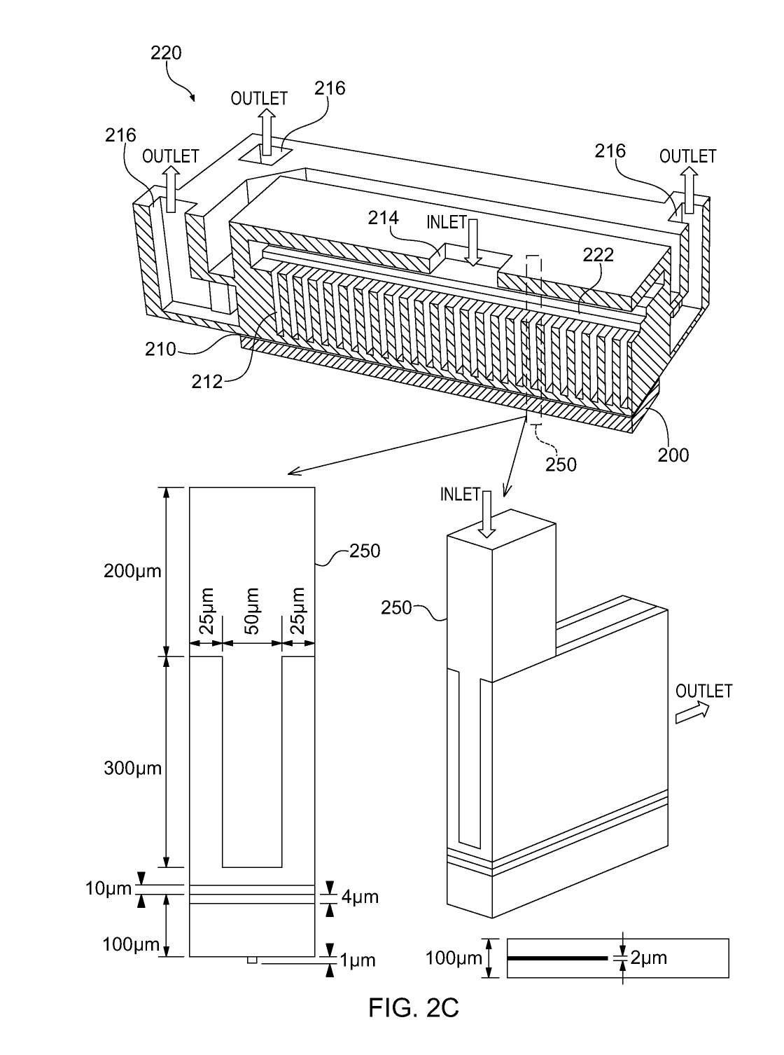

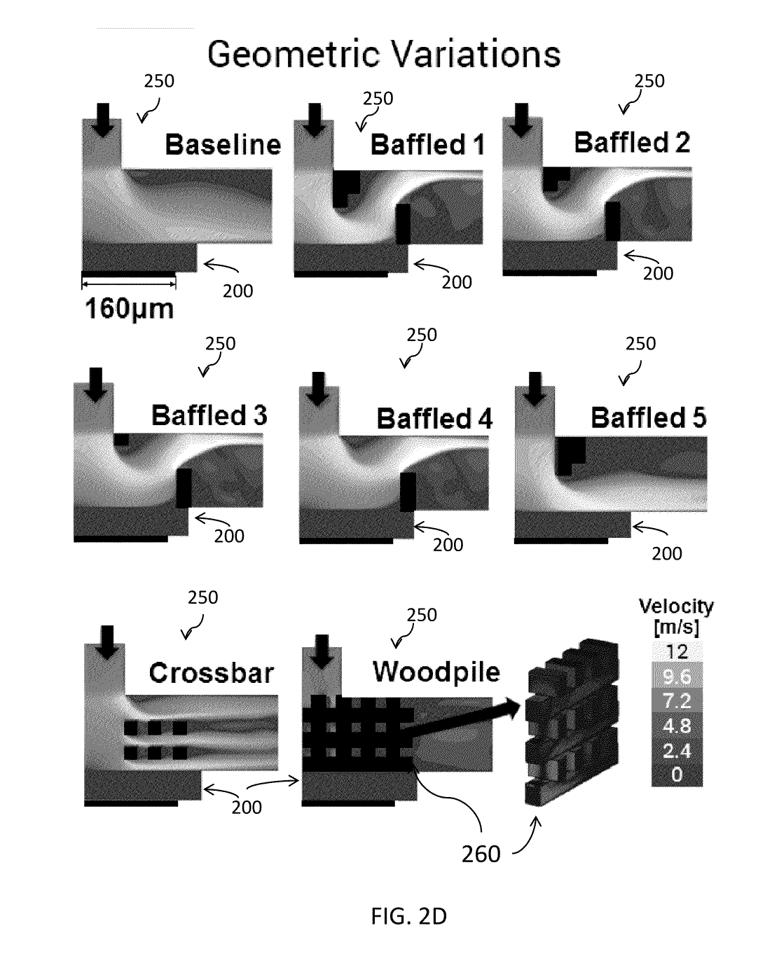

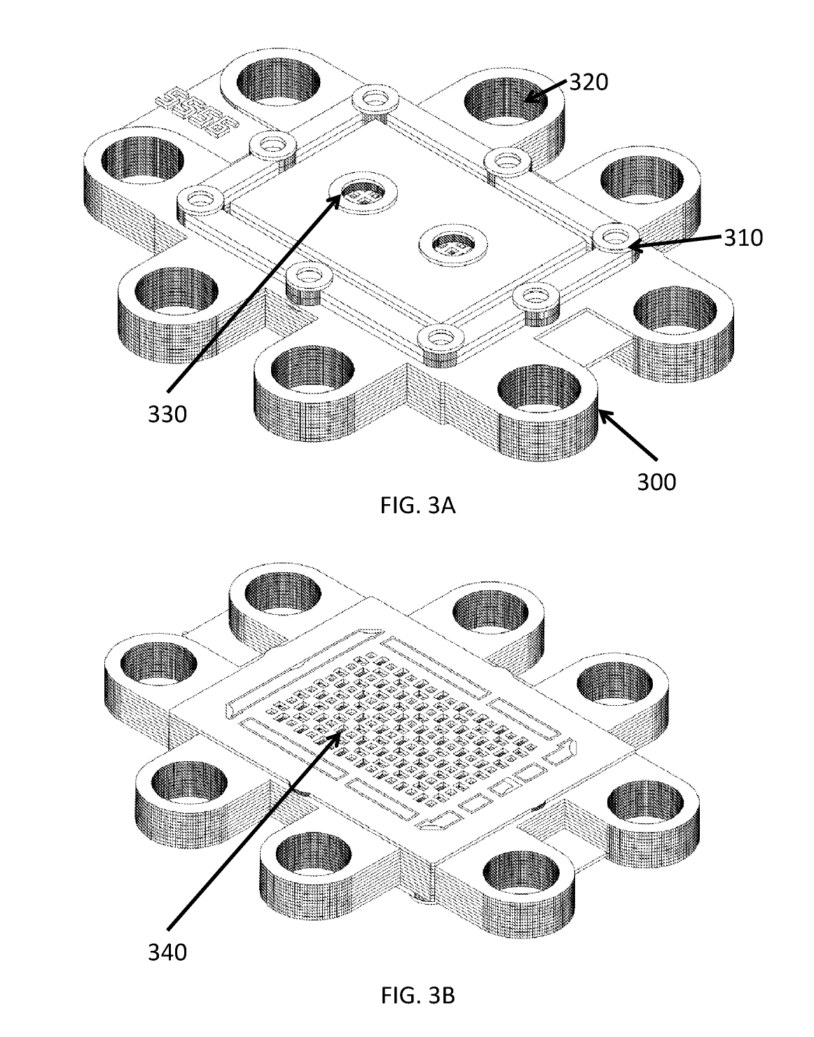

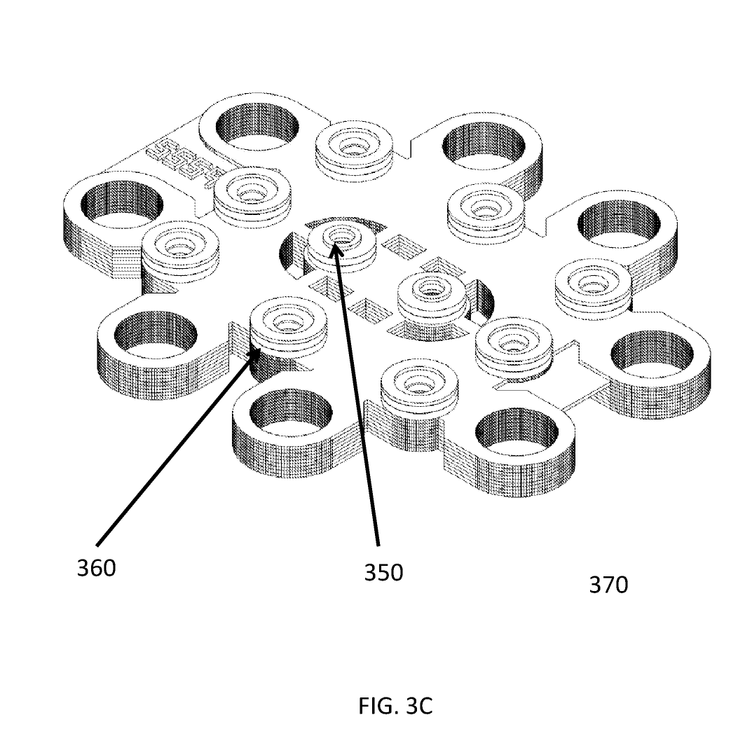

FIG. 2A illustrates an exploded view in cross section of FIG. 2B, which may be viewed as including three constitutive parts: i) a microelectronics device 200, which may be an integrated circuit such as a GaN HEMT RF amplifier; ii) a microfabricated thermal spreader 220 with integrated fluidic heat exchanger and flow regions; and iii) a stress transition stack or thermal interface material 210 used to bond the microelectronics device 200 to the thermal spreader 220. The microelectronics device 200 may include a GaN layer 204; a HEMT transistor 202 with its gate, source, and drain; and, a silicon carbide (SiC) substrate 206 that may be anywhere from 30 microns to 100 microns thick in typical configurations. Alternatively, the microelectronics circuit could be fabricated on a different wafer substrate, such as silicon or gallium arsenide. The thermal interface material 210 may be solder (such as gold-tin eutectic solder), conductive epoxy (such as a material from NAMICS Corporation or Epoxy Technology Inc.), sintering silver paste or some other electrically and thermally conductive material. The thermal interface material 210 should generally be as thin as possible to minimize the thermal resistance created by this layer. The thermal spreader 220 may include a group of fins 212 (nominally metal, such as copper) that provide the larger surface area from which the heat may be transferred from the device 200 to the metal of those fins 212 and then to the liquid or fluid passing by the fins 212. The thermal spreader 220 may include an inlet or group of inlets 214 to bring fluid into the thermal spreader 220 and an outlet or group of outlets 216 to remove fluid from the thermal spreader 220. A channel or set of channels 213 may be cut into the fins 212 to allow transfer of the liquid from inlets 214 to outlets 216. Constriction of a passage through which the fluid flows or blocking or obstructing of said passage using a micromachined object can create disruptions of fluid flow that improve thermal transfer properties. An upper surface 218 is the surface against which the microelectronics device 200 may be bonded using the thermal interface material 210 and from which fins 212 are typically in direct conductive thermal contact. As shown by numeral 340 in FIG. 3B, the upper surface 218 shown in FIG. 2A may receive a relief pattern of holes to minimize the stress induced by the CTE differential between the microelectronic device 200 and the thermal spreader 220. The fins 212 may be optimized using thermal and fluidic flow finite element analysis to maximize the thermal conduction from the heat generating regions (e.g., transistors 202) of chip-level device 200, through thermal barriers of the chip substrate 206, any thermal interface material 210, then through the chip mounting surface 218 of the thermal spreader 220, and into the depth of the fins 212 such that the fluids flowing across the fin surfaces can optimally extract and carry away the heat. FIG. 2C shows a quarter-section view of a thermal spreader similar to what is shown in FIGS. 2A and 2B in a perspective view with details added. It can be seen that through the inlet a fluid is delivered into a distribution manifold region 222, before the fluid enters and flows into the region between fins 212. The fluid may then be collected in a second outlet manifold and then flow through the outlets. FIG. 2C highlights a unit cell of a fin 212 and expands upon it as unit cell 250. Part of two adjacent fins 212 are there seen in cross-section and perspective views along with the device and its corresponding thermal interfaces.

FIG. 2D illustrates how various flow disrupting structures “Baffled 1”-“Baffled 5”, “Crossbar”, “Woodpile” may be located between the fins 212 to optimize heat transfer, flow velocity, pressure drop, or other properties of the fluid in the thermal spreader. The purpose of the flow disrupting structures may be elimination of any static or “dead” regions of flow. Such baffles or disruptors may be used to both lower fluid flow velocities in regions that are excessively fast, for example, and to reduce negative reliability factors such as erosion corrosion. They may also be used to increase flow velocity from regions of low flow where greater heat transport is desired. Such a disruption may be accomplished by introducing one or more cross-bar joining regions between the fins, as is illustrated with the variety of cases shown.

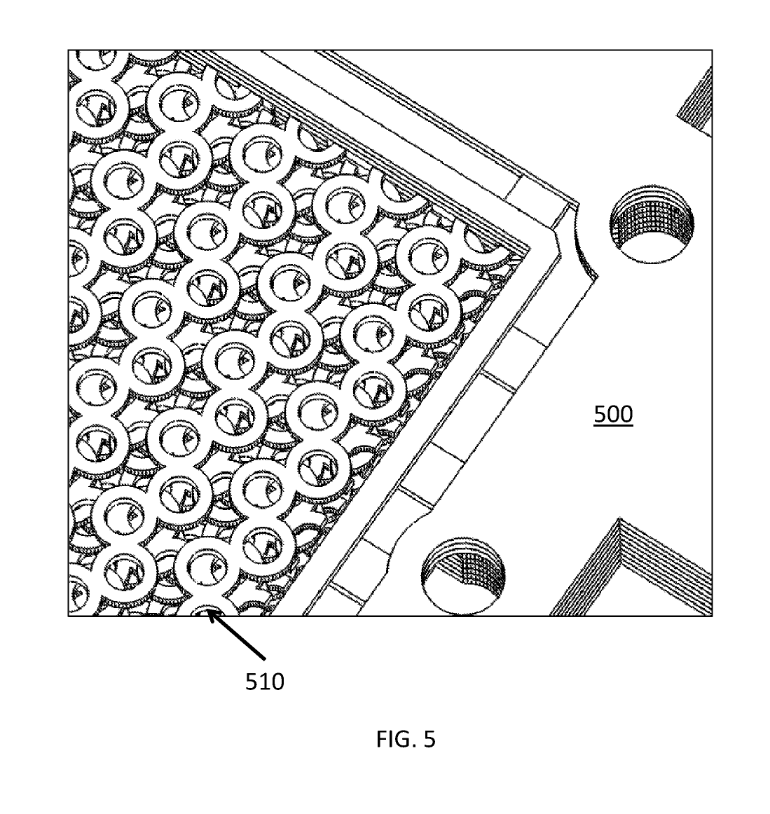

A baffle or cross-bar may be a solid section joining or located between two or more adjacent fins. Such bars or baffles can have a dramatic effect on regions of low flow near the surface of a fin. It can be seen that a baffle like “Baffled 5” of FIG. 2D can produce strong flow on the surface of the fin adjacent to the inlet region. The word “fins” is used to describe these features, but they may be offset rings, as shown in FIG. 5, a combination of rings and fins, or some other geometry. Baffles may take various forms, such as a “wood pile” structure 260 or a “cross-bar” structure, shown in the lower left of FIG. 2D. The surface finish of the microfabricated heat structure may be an important consideration to create reliable systems. The surfaces against which the fluid flows, especially in regions of high velocity, may be prone to erosion if those velocities are above a certain threshold. As a result, harder materials may be used to make the device or may be coated on the device. Coating on copper may include materials such as Ni, Pt, Rh, or ceramics. These materials may be applied conformally through a chemical process such as electroless plating, electrolytic plating, or atomic layer deposition. If metals are used, considerations to limit Galvanic interactions between dissimilar metals may be required, which is a reason that ceramic coatings may be preferred.

FIGS. 3A and 3B show the back and front respectively of a microfabricated thermal spreader 300 with increased fidelity of the features that are used to make the device practical. The layers or strata used to form a thermal spreader 300 may be seen on the edge of the device. The thermal spreader 300 may include one of several outlet structures 310 and inlet structures 330. A hole 320 may be used to mechanically align the thermal spreader 300 to a fixture to which it is attached. Upper surface 340 may be a patterned surface against which a microelectronics chip may be bonded. By providing a pattern of metal and air, the effective CTE of the upper surface 340 can be decreased to reduce the stresses caused by bonding a device directly to the thermal spreader 300. FIG. 3C shows an exemplary alternative microfluidic spreader 370 with slightly different features for its inlets 350 and its outlets 360 than inlet structures 330 and outlet structures 310 of FIG. 3A, 3B. The inlet 350 may have an inner ring that is smaller than the surface against which the tubes connecting spreader 370 to external fluidic heat exchangers is mated. This provides improved alignment of the two pieces. As an alternative, an outer ring 360 that is larger in diameter than the tube that connects to it may be provided to facilitate alignment for these parts to be mated and stress relief of the joint that seals the external tube to spreader 370.

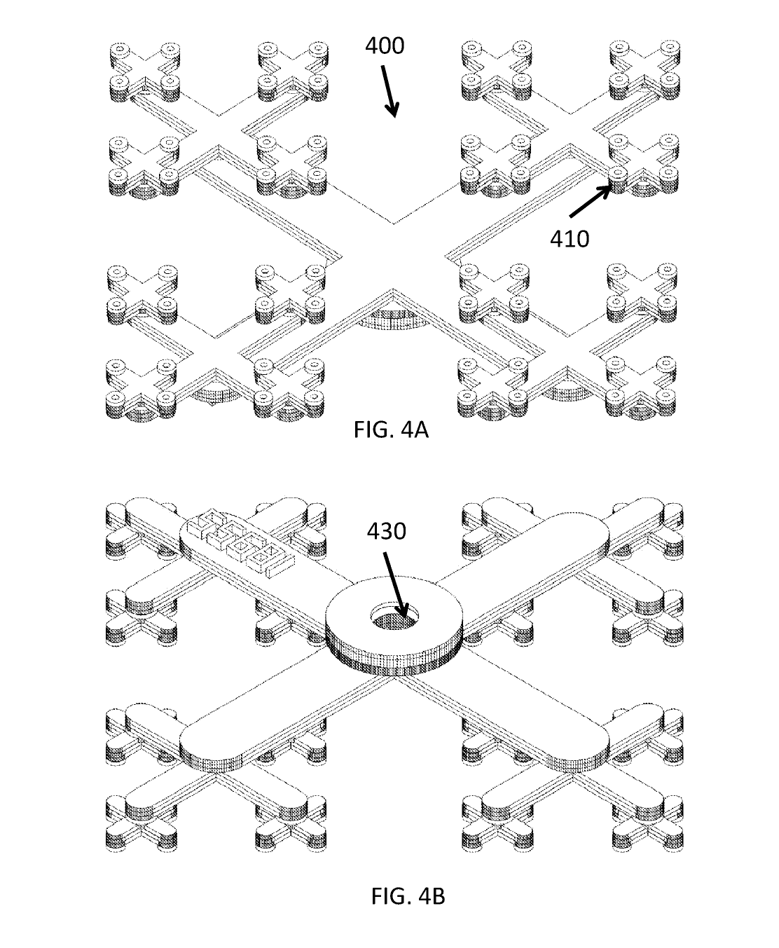

FIGS. 4A and 4B show a microfabricated chandelier structure 400 that may be used to distribute liquid from an inlet 430 to outlets 410. A similar structure may be used to return the liquid from the thermal spreading structure (not shown in this image).

FIG. 5 shows an inset view of a particular microfabricated thermal structure 500 that has a series of rings 510 that have been slightly offset from layer to layer. Using a multi-layer fabrication process, the offset rings 510 provide an increased surface area than can be provided with non-offset features produced by a given fabrication process. By creating local features of this nature, or of other unique constructions, the temperature rise of the microelectronic device may be minimized for a given set of constraints.

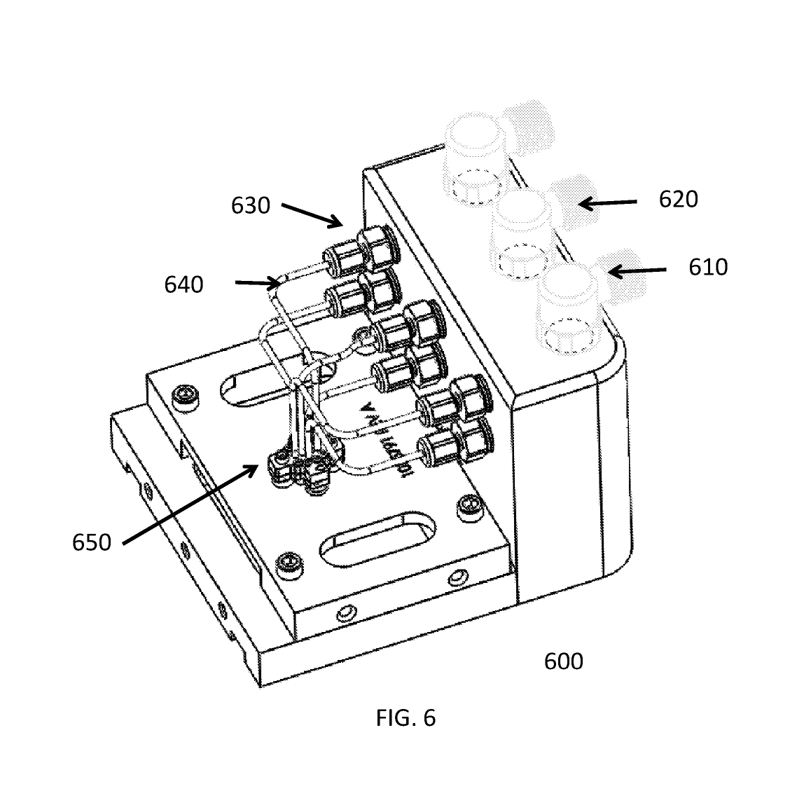

FIG. 6 shows a possible apparatus 600 that may be used to connect the thermal spreader assembly 650 to standard plumbing hardware. The system includes and inlet path 620 and outlet path 610. Connection 630 may be one of several standard Swagelok®-style fittings used to connect tubing 640 from the thermal spreader assembly 650 to the standard connection inlets and outlets 610, 620. This is only one possible way of connecting, but it is illustrative of other possible concepts. The thermal spreader assembly 650 may have epoxied or soldered tubing 640 permanently affixed to it.

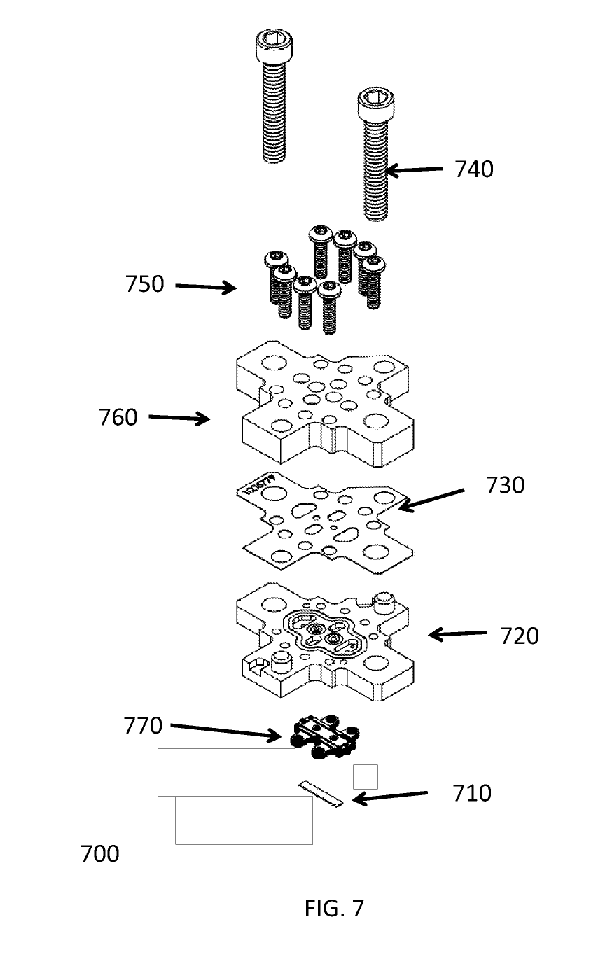

FIG. 7 is an exploded view of a thermal spreader assembly 700. Part 710 is a microelectronic device being cooled. Part 770 is a microfabricated thermal spreader on which the microelectronic device 710 is mounted. Part 720 is a bottom die plate on which the thermal spreader is assembled. In this case, larger, stress-relieved tubing can be connected to thermal spreader assembly 700 than would otherwise be possible if an attempt were made to connect directly to the microfabricated thermal spreader 770. Part 730 is a metal gasket in accordance with the present invention that provides a seal between a top die plate 760 and the bottom die plate 720. By making the gasket 730 of copper, which is a softer material than top die plate 760 and the bottom die plate 720, the gasket 730 may deform to provide the proper seal using such as structure as a tongue and groove feature spread between the top die plate 760 and bottom die plate 720. By replacing the metal gasket and the rest of the assembly shown (with the aid of the screws shown to apply uniform pressure to the gasket, 740, and the screws, 750, used to affix the assembly to the test setup), many devices may readily be fluidically interconnected, and then exchanged with the same fluid delivery setup.

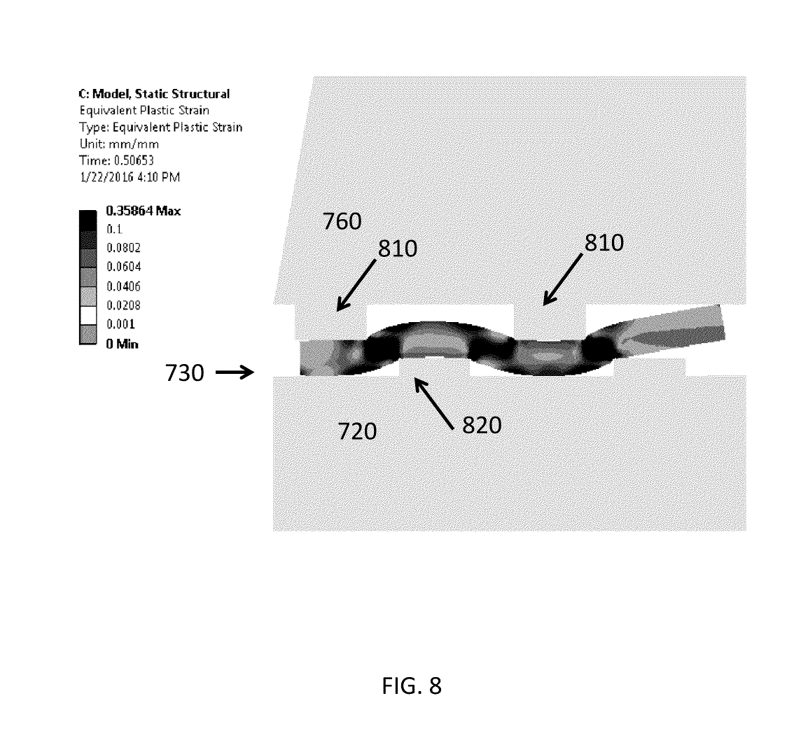

FIG. 8 depicts axisymmetric analysis results showing contours of plastic strain in a small photo-patterned gasket 730. In this case the gasket 730 was formed of copper electrodeposited in a photopatterned mold material. The mold material was dissolved and the gasket released from the substrate on which it was formed using a sacrificial underlayer. The gasket 730 was originally flat and was squeezed between concentric protrusions 810 on the top die plate 760 and a matching protrusion 820 on the bottom die plate 720 to form the gasket to the sealing surfaces. Such gaskets have been tested in these fluidic systems and found to be reliable means of sealing the components. Such gaskets can be disposed and replaced when devices are changed, service is needed, or hardware is replaced. Elastomer gaskets can be repeatedly used, however copper has advantages such as high thermal and electrical conductivity, pressure handing, and hermeticity.

These and other advantages of the present invention will be apparent to those skilled in the art from the foregoing specification. Accordingly, it will be recognized by those skilled in the art that changes or modifications may be made to the above-described embodiments without departing from the broad inventive concepts of the invention. It should therefore be understood that this invention is not limited to the particular embodiments described herein, but is intended to include all changes and modifications that are within the scope and spirit of the invention as set forth in the claims.

What is claimed is:

1. A thermal spreader, comprising a surface for mounting to a device to be cooled or heated, and a plurality of microstructures in thermal communication with the surface, a selected pair of the microstructures having a passageway extending therebetween, the passageway comprising a flow disruptor disposed therein to increase heat transfer therein.

2. The thermal spreader according to claim 1, wherein microstructures comprise one or more of fins or offset rings or combinations thereof.

3. The thermal spreader according to claim 1, wherein the flow disruptor comprises one or more of baffles, diverters, apertures, a cross-bar structure, a woodpile structure, or combinations thereof.

4. The thermal spreader according to claim 1, wherein the microstructures are coated in an erosion or corrosion resistant material.

5. The thermal spreader according to claim 4, wherein the material comprises Ni, Pt, Rh, ceramics, or combinations thereof.

6. The thermal spreader according to claim 1, wherein the device to be cooled comprises a semiconductor-based microwave amplifier.

7. The thermal spreader according to claim 1, wherein the pair of microstructures comprises a pair of fins, and wherein the flow disruptor comprises a woodpile structure.
